(19) United States
(12) Patent Application Publication
(10) Pub. No.: US 2003/0128045 A1
(43) Pub. Date: Jul. 10, 2003

(54) Apparatus and method for testing semiconductor storage device

(75) Inventor: Takehiro Ochi, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 10/174,994

(22) Filed: Jun. 20, 2002

(30) Foreign Application Priority Data
Jan. 7, 2002 (JP) 2002-000279

(51) Int. Cl. G01R 31/26

(52) U.S. Cl. 324/765

(57) ABSTRACT

A test apparatus includes a plurality of test circuits, each test circuit having a connection section to be used for connecting a semiconductor device under test (DUT), such as DRAM; a driver circuit for sending a write signal to the connection section in response to a test pattern output from a test pattern generator; a timer for setting a pause time and read time of the DUT; a determination circuit which is connected to the connection section, determines whether the DUT is defective or acceptable in accordance with the level of a signal read from the semiconductor storage device, and transmits a result of determination to a result processing circuit; and a counter for controlling operation of the driver circuit and operation of the determination circuit in response to the test pattern. The apparatus simultaneously tests a plurality of semiconductor storage devices under test connected to the connection sections of the respective test circuits.

### BACKGROUND OF THE INVENTION

1. Field of the Invention

The present invention relates to an apparatus and method for testing a semiconductor storage device, and more particularly, to an apparatus and method for simultaneously testing a plurality of semiconductor storage devices which require rewriting or refreshing operation and provide different levels of performance.

2. Background Art

In many cases, at the time of testing of a semiconductor storage device (hereinafter called a “memory device”), in consideration of productivity, a plurality of memory devices are usually connected to a tester and subjected to simultaneous measurement. In this case, the tester tests the memory devices, by means of applying an identical electric signal to the memory devices. This method enables measurement of a plurality of memory devices by one operation. Even in terms of conservation of hardware/software resources to be used for controlling the tester, the method is greatly advantageous.

However, when memory devices provide different levels of performance and an attempt is made to determine capabilities of the individual memory devices, difficulty is encountered in measuring the memory devices by one operation. The reason for this is that measurement customized to each of the memory devices having different capabilities must be performed on a one-by-one basis.

As mentioned above, the related-art tester must measure memory devices of different capabilities on a one-by-one basis. However, measurement of memory devices on a per-device basis involves consumption of a very long measurement time. This results in a drop in processing capability, which in turn leads to a hike in testing costs. This problem can be solved by means of preparing test signal input/output circuits and result determination circuits, which are equal in number to memory devices under test, and simultaneously measuring and determining capabilities of the memory devices. However, this makes the configuration of the tester complex, thereby posing problems, such as a cost hike or difficulty in signal control.

### SUMMARY OF THE INVENTION

The present invention has been conceived to solve such problems and aims at providing a test apparatus and method which enable simultaneous testing of a plurality of memory devices, the memory devices providing different levels of performance; particularly, different levels of pausing capability.

According to one aspect of the present invention, an apparatus for testing a semiconductor storage device including a plurality of test circuits. Each test circuit comprises a connection section, a driver circuit, a timer, a determination circuit and a counter. The connection section is to be used for connecting a semiconductor storage device under test which requires rewriting or refreshing operation. The driver circuit is for sending a write signal to the connection section in response to a test pattern output from a test pattern generator. The timer is for setting a pause time and read time of the semiconductor storage device under test. The determination circuit is connected to the connection section. The determination circuit determines whether the semiconductor storage device is defective or acceptable in accordance with the level of a read signal read from the semiconductor storage device. The determination circuit transmits a result of determination to a result processing circuit. The counter is for controlling operation of the driver circuit and operation of the determination circuit in response to the test pattern. A plurality of semiconductor storage devices under test connected to the connection sections of the respective test circuits are tested simultaneously.

According to another aspect of the present invention, there is provided a method for testing a semiconductor storage device using an apparatus for testing a semiconductor storage device including a plurality of test circuits. Each test circuit comprises a connection section, a driver circuit, a timer, a determination circuit and a counter. The connection section is to be used for connecting a semiconductor storage device under test which requires rewriting or refreshing operation. The driver circuit is for sending a write signal to the connection section in response to a test pattern output from a test pattern generator. The timer is for setting a pause time and read time of the semiconductor storage device under test. The determination circuit is connected to the connection section. The determination circuit determines whether the semiconductor storage device is defective or acceptable in accordance with the level of a read signal read from the semiconductor storage device. The determination circuit transmits a result of determination to a result processing circuit. The counter is for controlling operation of the driver circuit and operation of the determination circuit in response to the test pattern. A plurality of semiconductor storage devices under test connected to the connection sections of the respective test circuits are tested simultaneously. In the method, the plurality of semiconductor storage devices under test which provide different levels of pausing capability are tested simultaneously.

According to another aspect of the present invention, there is provided a method for testing a semiconductor storage device using an apparatus for testing a semiconductor storage device including a plurality of test circuits. Each test circuit comprises a connection section, a driver circuit, a timer, a determination circuit and a counter. The connection section is to be used for connecting a semiconductor storage device under test which requires rewriting or refreshing operation. The driver circuit is for sending a write signal to the connection section in response to a test pattern output from a test pattern generator. The timer is for setting a pause time and read time of the semiconductor storage device under test. The determination circuit is connected to the connection section. The determination circuit determines whether the semiconductor storage device is defective or acceptable in accordance with the level of a read signal read from the semiconductor storage device. The determination circuit transmits a result of determination to a result processing circuit. The counter is for controlling operation of the driver circuit and operation of the determination circuit in response to the test pattern. A plurality of semiconductor storage devices under test connected to the connection sections of the respective test circuits are tested simultaneously. The determination circuit is constituted of a comparator for comparing the read signal with a predetermined level. In the method, the plurality of semiconductor storage devices under test which provide different levels of pausing capability are tested simultaneously.

Since the apparatus and method of testing a semiconductor storage device has been configured in the manner as mentioned above, a plurality of DUTs which provide different levels of pausing capability are tested simultaneously. Hence, a determination result can be determined individually for each DUT.

A plurality of DUTs can be simultaneously tested by means of pattern generators and result processing circuits which are fewer in number than DUTs to be measured.

Other and further objects, features and advantages of the invention will appear more fully from the following description.

### BRIEF DESCRIPTION OF THE DRAWINGS

FIG. 1 is a block diagram showing the configuration of a tester according to the first embodiment.

FIG. 2 is a diagram showing the procedures for simultaneously subjecting to a pause test two DUTs.

### DETAILED DESCRIPTION OF THE PREFERRED EMBODIMENTS

First Embodiment

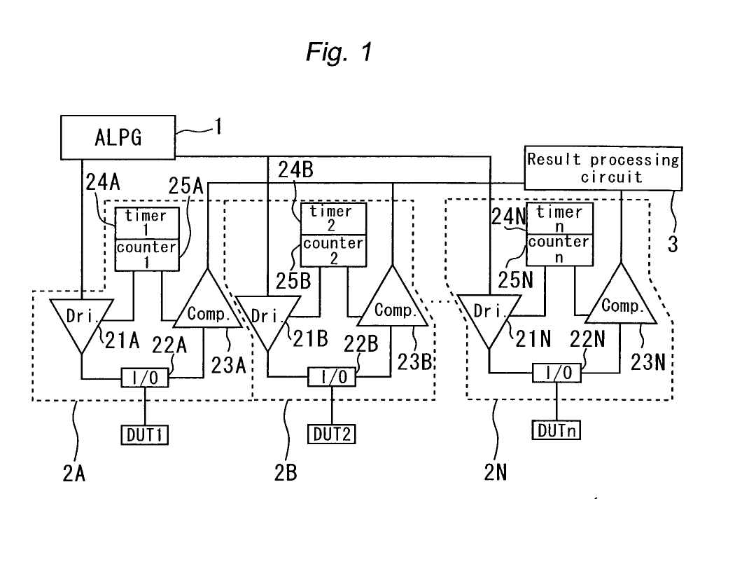

A first embodiment of the invention will now be described by reference to the accompanying drawings. FIG. 1 is a block diagram showing the configuration of a tester according to the first embodiment. FIG. 1 shows the configuration of a tester for a pause test purpose for testing a characteristic of holding a signal during the course of testing of a memory device.

The pause test is targeted for a memory device requiring a writing or refreshing operation; for example, DRAM. A target memory device is subjected to total rewriting operation, whereby the device is set to a predetermined signal level. After having been left (paused) for a predetermined period of time, the memory device is subjected to total reading operation. The memory device is then determined to be defective or acceptable by means of checking whether or not a ratio of a read signal level to a write signal level is higher than a predetermined level; e.g., 80%. A pause time (i.e., pausing capability) for retaining the write signal level differs from one memory device to another. Hence, each of the memory devices is subjected to a search several times by means of a detection method called a well-known binary research method (i.e., a retrieval based on the dichotomy), thereby detecting a pause time.

The configuration of the tester according to the first embodiment which simultaneously tests a plurality of memory devices for which different pause times have been detected will now be described by reference to FIG. 1.

As shown in FIG. 1, reference numeral 1 designates a test pattern generator for generating a test pattern for testing purpose. Details of a test pattern will be described later.

Reference numerals 2A, 2B, . . . 2N designate test circuits which are provided in equal number to memory devices under test (hereinafter abbreviated as “DUTs”) having different levels of pause performance upon receipt of a test pattern output from the tester pattern generator 1. The test circuits 2A, 2B, . . . 2N consists of the each portion described later. Although the following description is directed to only a test circuit 2A, the remaining test circuits 2B, . . . 2N are constructed in the same manner.

Reference numeral 21A designates a driver circuit which produces a test signal corresponding to the test pattern output from the test pattern generator 1 and writes the thus-produced test signal into a DUT1 to be described later. Reference numeral 22A designates a connection section to be connected to a DUT1 which is one of DUTs to be tested by the test circuit 2A. The connection section 22A is connected to the driver circuit 21A and imparts to the DUT1 a write signal output from the driver circuit 21A. At the time of reading operation, the connection section 22A imparts a read signal output from the DUT1 to a determination circuit to be described later. Reference numeral 23A designates a determination circuit which checks the level of a signal read from the DUT1 by way of the connection section 22A, to thereby determine whether the DUT1 is defective or acceptable. The determination circuit 23A is constituted of a comparator which compares the thus-read signal with a predetermined reference value (not shown) and determines the DUT1 as acceptable when the loaded signal is higher than the reference value.

Reference numeral 24A designates a timer for setting a pause time and a reading time of DUTs 1. Reference numeral 25A designates a counter which controls operation of the driver circuit 21A and that of the determination circuit 23A in conjunction with a timer.

For instance, when a signal is written into the DUT1, an H signal is imparted to the driver circuit 21A, thereby activating the driver circuit 21A. Further, an L signal is imparted to the determination circuit 23A, to thereby deactivate the determination circuit.

At the time of pausing operation, an L signal is imparted to the driver circuit 21A and the determination circuit 23A, thereby deactivating the driver circuit 21A and the determination circuit 23A. Thus, input/output of signal into/from the DUT1 is interrupted.

At the time of reading operation, an H signal is imparted to the determination circuit 23A, thus activating the determination circuit 23A. Further, an L signal is imparted to the driver circuit 21A, thus deactivating the driver circuit 21A.

Reference numeral 3 designates a result processing circuit which collects determination results from determination circuits provided in respective test circuits and summarizes the thus-collected results.

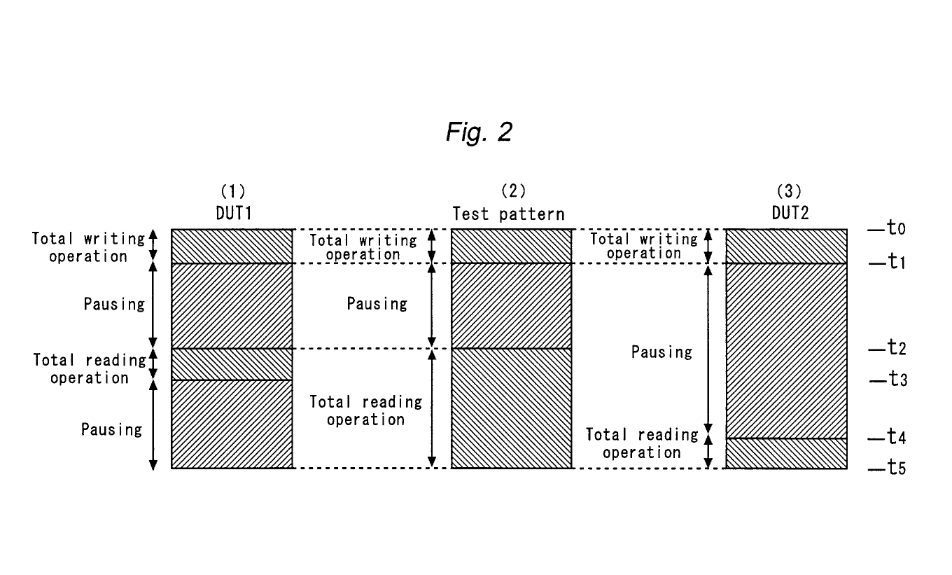

By reference to FIG. 2, there will now be described procedures for simultaneously subjecting to a pause test two DUTs; that is, a DUT1 and a DUT2, which have different levels of pausing capability.

As shown in FIG. 2, (2) denotes settings of a test pattern, wherein t0 designates a start, and t5 designates an end. (1) designates procedures for testing the DUT1 corresponding to the test pattern, and (3) designates procedures for testing the DUT2 corresponding to the test pattern. In this case, the pause time of the DUT1 and the pause time of the DUT2 have been admitted as a result of the DUTs 1, 2 having been subjected to a binary search several times.

In response to a test pattern, the DUT1, DUT2 are subjected to total writing from time t0 to time t1. At time t1, total writing operation is completed. Simultaneously, a timer 24A in which the pause time of the DUT1 is set and a timer 24B in which the pause time of the DUT2 is set are activated, and the DUT1, DUT2 start pausing operations.

During a period of pause time, a counter 25A of the DUT1 and a counter 25B of the DUT2 operate, to thereby send a predetermined signal to the driver circuit 21A and the determination circuit 23A of the DUT1 and to the driver circuit 21B and the determination circuit 23B of the DUT2. As a result, signals input to and output from the DUTs 1, 2 are interrupted.

Of a plurality of pause times of a plurality of DUTs, a pause time of a test pattern is set to the shortest period of time. Hence, a timer of each DUT instructs completion of the pausing operation simultaneously with completion of a pause of the test pattern or at a subsequent point in time. As shown in FIG. 2, the pause time of the DUT1 is identical with the pause time of the test pattern. Hence, the DUT1 terminates the pausing operation at time t2 and shifts to total reading operation until time t3 in response to the test pattern. At this time, the pause time of the DUT2 is continued by the timer 24B. Moreover, signals input to and output from the driver circuit 21B and the determination circuit 23B are interrupted by the counter 25B. For this reason, as illustrated, the pausing operation is continued.

Since the DUT1 finishes a total reading operation at time t3, a pause time is set by the timer 24A until time t5, at which the test of the DUT2 is completed. The counter 25A sends a predetermined signal to the driver circuit 21A and the determination circuit 23A, thereby again interrupting signals input to and output from the DUT1.

The pausing operation of the DUT2 is completed at time t4. In response to an instruction for total reading of a test pattern issued at that point in time, total reading operation is performed until time t5. Reading of the DUT2 may be started from a leading address under control of the counter 25B. Alternatively, the reading operation may be started from any one of addresses under control of the timer 24B.

The determination circuit 23B compares the thus-read signal with a predetermined reference value, thereby determining whether the signal is greater than or less than the predetermined value. A result of determination as to whether the DUT2 is defective or acceptable is delivered to the result processing circuit 3. The determination circuit 23A makes a determination as to the DUT1 analogous to that mentioned above during a period of time from t2 to t3 during which the DUT1 is subjected to total reading operation. The result of determination is delivered to the result processing circuit 3. More specifically, at points in time when reading of the DUTs 1, 2 has been completed, a determination is made as to whether or not the DUT1 is defective or acceptable (PASS/FAIL) during a period of pause time from t1 to t2. Further, a determination is made as to whether or not the DUT2 is defective or acceptable (PASS/FAIL) during a period of pause time from t1 to t4. Simultaneously, a test is completed.

Since the apparatus and method of testing a semiconductor storage device has been configured in the manner as mentioned above, a plurality of DUTs which provide different levels of pausing capability are tested simultaneously. Hence, a determination result can be determined individually for each DUT.

A plurality of DUTs can be simultaneously tested by means of pattern generators and result processing circuits which are fewer in number than DUTs to be measured.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-279, filed on Jan. 7, 2002 including specification, claims, drawings and summary, on which the Convention priority of the present application is based, are incorporated herein by reference in its entirety.

1. An apparatus for testing a semiconductor storage device including a plurality of test circuits, each test circuit comprising:
a connection section to be used for connecting a semiconductor storage device under test which requires rewriting or refreshing operation;
a driver circuit for sending a write signal to said connection section in response to a test pattern output from a test pattern generator;
a timer for setting a pause time and read time of said semiconductor storage device under test;
a determination circuit which is connected to said connection section, determines whether said semiconductor storage device is defective or acceptable in accordance with the level of a read signal read from said semiconductor storage device, and transmits a result of determination to a result processing circuit; and
a counter for controlling operation of said driver circuit and operation of said determination circuit in response to said test pattern, wherein a plurality of semiconductor storage devices under test connected to said connection sections of said respective test circuits are tested simultaneously.

2. The apparatus for testing a semiconductor storage device according to claim 1, wherein said determination circuit is constituted of a comparator for comparing said read signal with a predetermined level.

3. A method for testing a semiconductor storage device using the apparatus for testing a semiconductor storage device including a plurality of test circuits, each test circuit comprising a connection section to be used for connecting a semiconductor storage device under test which requires rewriting or refreshing operation, a driver circuit for sending a write signal to said connection section in response to a test pattern output from a test pattern generator, a timer for setting a pause time and read time of said semiconductor storage device under test, a determination circuit which is connected to said connection section, determines whether said semiconductor storage device is defective or acceptable in accordance with the level of a read signal read from said semiconductor storage device, and transmits a result of determination to a result processing circuit, and a counter for controlling operation of said driver circuit and operation of said determination circuit in response to said test pattern, wherein a plurality of semiconductor storage devices under test connected to said connection sections of said respective test circuits are tested simultaneously,
wherein said plurality of semiconductor storage devices under test which provide different levels of pausing capability are tested simultaneously.

4. The method for testing a semiconductor storage device according to claim 3, wherein, after a plurality of semiconductor storage devices under test have been subjected to total writing operation, timers of respective test circuits are activated, thereby performing pausing operations, and a total reading operation is performed for each test circuit after completion of said pausing operation.

5. The method for testing a semiconductor storage device according to claim 4, wherein, during a period of the pause time, counters provided in the respective test circuits interrupt inputs to be sent to the semiconductor storage devices under test from driver circuits of the respective test circuits and outputs from the determination circuits.

6. The method for testing a semiconductor storage device according to claim 4, wherein a pause time of each test circuit is determined in accordance with a retaining characteristic of each of semiconductor storage devices under test which are connected to the connection sections of the respective test circuits.

7. The method for testing a semiconductor storage device according to claim 4, wherein, if reading operation of another test circuit has not yet being completed upon completion of reading operation of a predetermined test circuit, a counter of the test circuit that has finished reading operation interrupts an inputs to be sent from a driver circuit of the test circuit to the semiconductor storage device under test and an output from the determination circuit, thus bringing the test circuit into a standby condition.

8. A method for testing a semiconductor storage device using the apparatus for testing a semiconductor storage device including a plurality of test circuits, each test circuit comprising a connection section to be used for connecting a semiconductor storage device under test which requires rewriting or refreshing operation, a driver circuit for sending a write signal to said connection section in response to a test pattern output from a test pattern generator, a timer for setting a pause time and read time of said semiconductor storage device under test, a determination circuit which is connected to said connection section, determines whether said semiconductor storage device is defective or acceptable in accordance with the level of a read signal read from said semiconductor storage device, and transmits a result of determination to a result processing circuit, and a counter for controlling operation of said driver circuit and operation of said determination circuit in response to said test pattern, wherein a plurality of semiconductor storage devices under test connected to said connection sections of said respective test circuits are tested simultaneously, wherein said determination circuit is constituted of a comparator for comparing said read signal with a predetermined level,
wherein said plurality of semiconductor storage devices under test which provide different levels of pausing capability are tested simultaneously.

9. The method for testing a semiconductor storage device according to claim 8, wherein, after a plurality of semiconductor storage devices under test have been subjected to total writing operation, timers of respective test circuits are activated, thereby performing pausing operations, and a total reading operation is performed for each test circuit after completion of said pausing operation.

10. The method for testing a semiconductor storage device according to claim 9, wherein, during a period of the pause time, counters provided in the respective test circuits interrupt inputs to be sent to the semiconductor storage devices under test from driver circuits of the respective test circuits and outputs from the determination circuits.

11. The method for testing a semiconductor storage device according to claim 9, wherein a pause time of each test circuit is determined in accordance with a retaining characteristic of each of semiconductor storage devices under test which are connected to the connection sections of the respective test circuits.

12. The method for testing a semiconductor storage device according to claim 9, wherein, if reading operation of another test circuit has not yet being completed upon completion of reading operation of a predetermined test circuit, a counter of the test circuit that has finished reading operation interrupts an inputs to be sent from a driver circuit of the test circuit to the semiconductor storage device under test and an output from the determination circuit, thus bringing the test circuit into a standby condition.
